(19) United States
(12) Patent Application Publication
(10) Pub. No.: US 2022/0069073 A1
(43) Pub. Date: Mar. 3, 2022

(54) INTEGRATED CIRCUIT SYSTEM WITH SUPER JUNCTION TRANSISTOR MECHANISM AND METHOD OF MANUFACTURE THEREOF

(71) Applicant: Nanjing Zizhu Microelectronics Co., Ltd., Shanghai (CN)

(72) Inventors: Yi Su, Cupertino, CA (US); Hong Chang, Saratoga, CA (US)

(21) Appl. No.: 17/006,592

(22) Filed: Aug. 28, 2020

(51) Int. Cl. H01L 29/06; H01L 29/10; H01L 29/40; H01L 29/78; H01L 21/265; H01L 21/3065; H01L 21/765; H01L 29/66

(52) U.S. Cl. CPC H01L 29/0634; H01L 29/1095; H01L 29/407; H01L 29/7811; H01L 29/66734; H01L 21/26513; H01L 21/3065; H01L 21/765; H01L 29/7813

(57) ABSTRACT

An integrated circuit system including: a split gate super junction cell includes: a highly doped substrate including a first polarity; an epitaxial layer including the first polarity grown on the highly doped substrate; a stripe gate trench formed in the epitaxial layer; a stripe gate poly layer formed in the stripe gate trench; a dot body implant, including a second polarity, implanted adjacent to the stripe gate trench opposite the stripe gate poly layer; and a conductive column, including the second polarity, implanted in the center of the dot body implant and extending into the epitaxial layer.

### TECHNICAL FIELD

The present invention relates to the field of semiconductor manufacturing, and more specifically to metal oxide semiconductor (MOS) super junction power transistor structures.

### BACKGROUND

Developments in voltage control mechanisms have evolved over time. For example, the development of power supplies has moved from 10 to 20 volts direct current power supplies has migrated to 600 to 700 volt switching power supplies for commercial applications. During the development of the high-power devices, power transistors have slowly evolved as well. During the development, groups of intermediate voltage transistors that were gang switched, caused noise and reliability issues due to the switching characteristics of the individual transistors that were not exactly matched.

As the semiconductor technology changes and geometries shrink, maintaining reliable and operational power metal oxide semiconductor field effect transistors (MOSFETs) can be more problematic. High output capacitances and increased on resistance can make most Power MOSFETs unsuitable for active switching applications.

Thus, a need still remains for an integrated circuit system with super junction transistor mechanism. In view of the ever-increasing commercial competitive pressures, along with growing consumer expectations and the diminishing opportunities for meaningful product differentiation in the marketplace, it is increasingly critical that answers be found to these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

An embodiment of the present invention provides a method of manufacture of an integrated circuit system including fabricating a split gate super junction cell includes: providing a highly doped substrate including a first polarity; growing an epitaxial layer including the first polarity on the highly doped substrate; forming a stripe gate trench in the epitaxial layer; implanting a body implant, including a second polarity, adjacent to the stripe gate trench opposite the stripe gate poly layer; and implanting a conductive column, having the second polarity, in the center of the body implant and extending into the epitaxial layer.

An embodiment of the present invention provides an Integrated circuit system, including a split gate super junction cell includes: a highly doped substrate including a first polarity; an epitaxial layer including the first polarity grown on the highly doped substrate; a stripe gate trench formed in the epitaxial layer; a stripe gate poly layer formed in the stripe gate trench; a body implant, including a second polarity, implanted adjacent to the stripe gate trench opposite the stripe gate poly layer; and a conductive column, having the second polarity, implanted in the center of the body implant and extending into the epitaxial layer.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a top plan view of an integrated circuit system with super junction transistor mechanism in an embodiment of the present invention.

FIG. 2 is an example of a top plan view of the integrated circuit system in the section 2-2 of FIG. 1.

FIG. 3 is an exemplary cross-section of the integrated circuit system along the section line 3-3 of FIG. 2.

FIG. 4 is an exemplary cross-section of the integrated circuit system along the section line 3-3 of FIG. 2 in an alternative embodiment of the present invention

FIG. 5 is an exemplary cross-section of a wafer portion after a masking phase of processing.

FIG. 6 is an exemplary cross-section of a wafer portion after a trenching phase of processing.

FIG. 7 is an exemplary cross-section of a wafer portion after an oxide deposition phase of processing.

FIG. 8 is an exemplary cross-section of a wafer portion after a poly deposition and implant phase of processing.

FIG. 9 is an exemplary cross-section of a wafer portion after an ion implant phase of processing.

FIG. 10 is an exemplary cross-section of a wafer portion in a metal deposition phase of processing.

FIG. 11 is a flow chart of a method of manufacture of the integrated circuit system including a power metal oxide semiconductor field effect transistor (MOSFET) cell in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Where multiple embodiments are disclosed and described, having some features in common, for clarity and ease of illustration, description, and comprehension thereof, similar and like features one to another will ordinarily be described with like reference numerals.

For expository purposes, the term “horizontal” as used herein is defined as a plane parallel to the plane of an active surface of the top of the integrated circuit die, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “on” as used herein means and refers to direct contact among elements with no intervening elements. The term “processing” as used herein includes deposition of material, patterning, exposure, development, etching, cleaning, and/or removal of the material or trimming as required in forming a described structure. The term “system” as used herein means and refers to the method and to the apparatus of the present invention in accordance with the context in which the term is used. The terms “grown”, “grows”, or “growing” as used herein refers to the addition thickness added by way of chemical vapor deposition (CVD) or other deposition processes. The term “center” or “centered” refers to positioning an element so that it is equidistant from the edges of another element.

It is also understood that the nouns or elements in the embodiments can be described as a singular instance. It is understood that the usage of singular is not limited to singular but the singular usage can be applicable to multiple instances for any particular noun or element in the application. The numerous instances can be the same or similar or can be different.

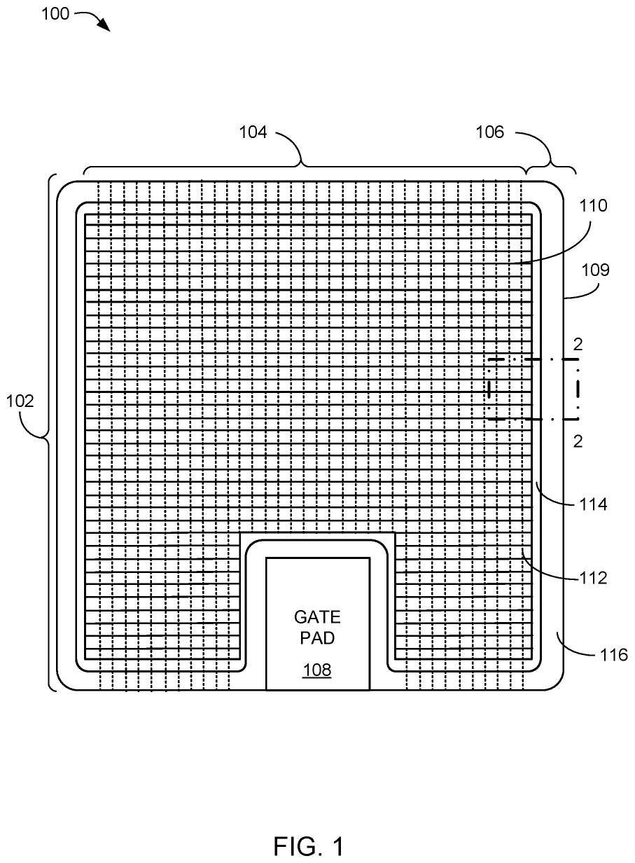

Referring now to FIG. 1, therein is shown a top plan view of an integrated circuit system 100 with super junction transistor mechanism in an embodiment of the present invention. The top plan view of the integrated circuit system 100 depicts an integrated circuit die 102, such as a super junction metal oxide semiconductor field effect transistor (MOSFET), prior to the application of source and gate metal. The integrated circuit die 102 can include an active region 104 and a termination region 106 surrounding the active region 104.

The active region 104 can be defined as the primary current carrying region of the integrated circuit die 102. The active region 104 can provide a current path between the source metal (not shown) and the drain metal (not shown), which would be applied opposite the source metal. The termination region 106 can provide an isolation space 114 and a gate metal region 116. The isolation space 114 can contain a stripe gate trench layer 112 that is isolated from the source metal and the gate metal that can cover the areas in the finished device. The isolation space 114 can provide a separation between the voltages applied to the top of the integrated circuit die 102.

A gate pad 108 can be formed on an outer edge 109 of the integrated circuit die 102. The gate pad 108 can be an area provided for electrical connection of the stripe gate trench layer 112. By way of an example, the gate pad 108 is shown centered on the outer edge 109 of the integrated circuit die 102, but it is understood that the gate pad 108 can be placed anywhere along the outer edge 109 of the integrated circuit die 102. The active region 104 can include an array of interconnect metal 110 and an array of the stripe gate trench layer 112. The termination region 106 can include the stripe gate trench layer 112 without the presence of the interconnect metal 110. It will be understood by one having ordinary skill in the art that the termination region 106 encompasses the outer edge 109 of the integrated circuit die 102 to surround the active region 104. The interconnect metal 110 can provide electrical connection between an array of source implants (not shown) that will be described below.

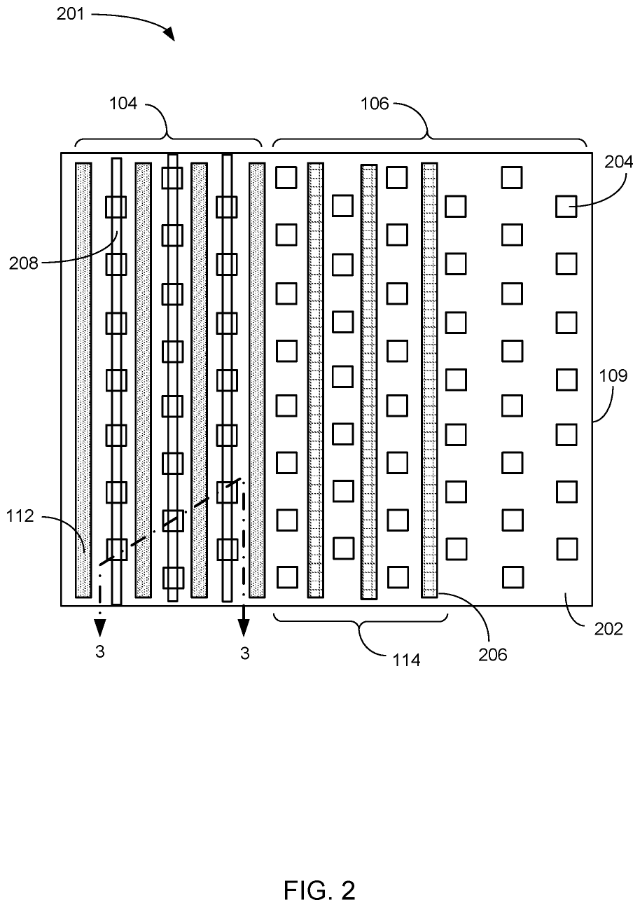

The relationship of the active region 104 and the termination region 106 will be further explained in FIG. 2 by way of the section 2-2 shown on the outer edge 109 of the integrated circuit die 102. The section 2-2 is an example only since the termination region 106 surrounds the active region 104.

As an example, the integrated circuit die 102 can include a source contact metal (not shown) applied in the active region 104 and a gate metal (not shown) on the gate pad 108 and around the outer edge 109 of the integrated circuit die 102 with an isolation space 114 between the source metal and the gate metal.

Referring now to FIG. 2, therein is shown an example of a top plan 201 view of the integrated circuit system 100 in the section 2-2 of FIG. 1. The top plan view 201 of the integrated circuit system 100 in the section 2-2 depicts the termination region 106, including the isolation space 114 adjacent to the active region 104. The termination region 106 can extend to the outer edge 109.

An epitaxial layer 202 including a first polarity, such as an N-type doped polarity, can include an array of dot column implant 204 having a second polarity, such as a P-type doped polarity. By way of a specific example the dot column implant can be a P-type implant extending into the N-type epitaxial layer. The dot column implant 204 can be formed to array across the active region 104 and the termination region 106. The isolation space 114 can include a number of a floating trench 206 contained within. By way of an example, three or more of the floating trench 206 can fit within the isolation space 114. It is understood that any number of the floating trench 206 can be designated within the isolation space 114.

The number of the floating trench 206 formed within the isolation space can be dependent on the target voltage range of the integrated circuit die 102 of FIG. 1. By way of an example, if the integrated circuit die 102 is to operate up to 25 Volts, a single one of the floating trench 206 can be implemented. If the integrated circuit die 102 is to operate between 30 Volts and 40 Volts, two of the floating trench 206 can be implemented. As the voltage capability of the integrated circuit die 102 is increased additional ones of the floating trench 206 can be added, such that three of the floating trench 206 can support between 60 Volts and 250 volts. Higher voltages would require additional instances of the floating trench 206.

As an example, the floating trench 206 is formed in the epitaxial layer 202 to a width of 0.45 μm with a tolerance of 0.2 μm. Further for example, the floating trench 206 can be formed with a depth of approximately 1.0 μm by a dry etching process. Continuing the example, the floating trench 206 can be constructed or formed in the same or similar manner as the stripe gate trench layer 112. By way of an example, the floating trench 206 is not connected to a voltage source or each other and preforms an isolation function to surround the active region 104.

As an example, the active region 104 can include a number of the stripe gate trench layer 112 formed between columns of the dot column implant 204. The stripe gate trench layer 112 can be constructed similar in size as the floating trench 206, but connection of the stripe gate trench layer 112 can be different because the stripe gate trench layer 112 can be designed to carry the gate voltage that can be provided by the gate metal, which will be discussed later.

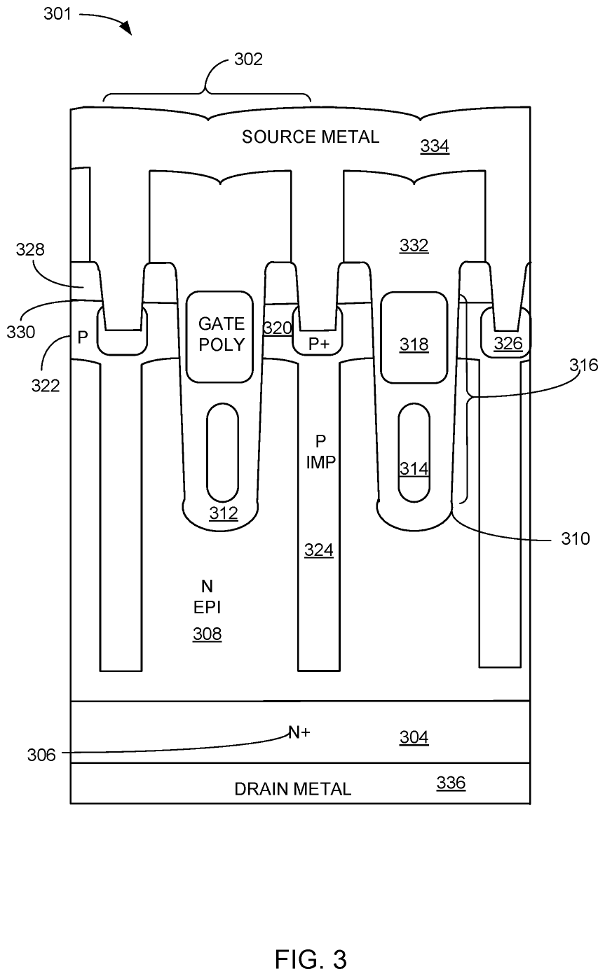

In this example, the dot column implant 204 located in the active region 104 can be coupled in columns by a stripe source contact 208 including a higher concentration of the second polarity, such as P+. The stripe source contact 208 can be coupled to a source metal (not shown). A section line 3-3 shows the relationship of the elements in FIG. 3. By way of an example, the dot column implant 204 is shown in a sharp rectangle shape, but the shape can also be a circular shape, an oval shape, or a rounded corner rectangle without changing the invention.

It has been discovered that the size of the isolation region 114 can be adjusted to accommodate the number of the floating trench 206 required to support the target voltage for the integrated circuit die 102, such as a super junction metal oxide semiconductor field effect transistor (MOSFET). Since the construction of the stripe gate trench layer 104 and the floating gate 206 are the same, the target operating voltage can be customized by the application of the source metal in a final step of manufacturing. The ability to customize the integrated circuit die 102 in a final step of manufacturing can save time and money for the manufacturing process and allow different target voltages yielded from the same semiconductor wafer improving the manufacturing process.

Referring now to FIG. 3, therein is shown an exemplary cross-section 301 of the integrated circuit system 100 along the section line 3-3 of FIG. 2. In this example, the cross-section 301 of the integrated circuit system 100 depicts two of a split gate super junction cell 302 in the active region 104 of FIG. 1. The construction of the power metal oxide semiconductor field effect transistor (MOSFET) cell including fabricating the split gate super junction cell 302 is described below. The split gate super junction cell 302 can be considered to be a MOSFET 302 and will be recognized by those skilled in the art.

In this example, a heavily doped substrate 304, including a first polarity 306 for example can provide a dopant concentration in the range of 2.2×10¹⁹ to 7.2×10¹⁹ per cm³. The heavily doped substrate 304 can be covered by forming an epitaxial layer 308, including the first polarity 306, on the heavily doped substrate 304. A stripe gate trench 310 formed in the epitaxial layer 308 can be lined with a liner oxide layer 312, which is an insulator. A stripe poly layer 314, such as a heavily doped polysilicon of the first polarity 306, can be formed to enclose the stripe poly layer 314. A stripe gate poly layer 318, can be formed above the stripe poly layer 314, which acts as the gate of the stripe split gate structure 316. The stripe gate poly layer 318 can be formed of a heavily doped polysilicon of a first polarity 306.

A body implant 320, of the second polarity 322, can be implanted between two instances of the stripe gate trench 310. A conductive column 324, of the second polarity 322, can be formed centered between the two instances of the stripe gate trench 310 and including a depth at least twice the depth of the stripe gate trench 310. By way of a specific example the conductive column 324 can be a P-type column Further details of the construction are described in later figures.

A stripe source contact implant 326 can be formed, by ion implant in the body implant 320. Source region 328 can be formed by ion implant on a silicon surface 330. An oxide cover 332 can be formed of Borophosphosilicate Glass (BPSG) or low temperature oxide (LTO) by deposition on top of the stripe gate poly layer 318.

A source metal 334, such as Aluminum (Al), Copper (Cu), can be applied directly on the stripe source contact implant 326 and the oxide cover 332. The stripe poly layer 314 can be a field plate, which is electrically connected to the source metal 334 for improving break-down voltage drain to source (BVdss) of the MOSFET 302, the gate charge, and the gate-drain charge reduction for faster switching. A drain metal 336, which can include Titanium (Ti), Nickle (Ni), Silver (Ag), combinations, or alloys thereof, can be applied to the heavily doped substrate 304.

It has been discovered that the split gate super junction cell 302 can provide faster switching, higher break-down voltage (BV), and low conduction resistance (Rdson) based on the split gate super junction construction and the presence of the conductive column 324. It is understood that the first polarity 306 is shown to be N-type doped silicon and the second polarity is shown to be P-type doped silicon, but they can be reversed without changing the invention. The split gate super junction cell 302 can also provide improved linear mode of operation due to the conductive column 324 providing additional voltage blocking capability. It is also understood that the conductive column 324 can be formed as a dot or a stripe implementation without changing the function.

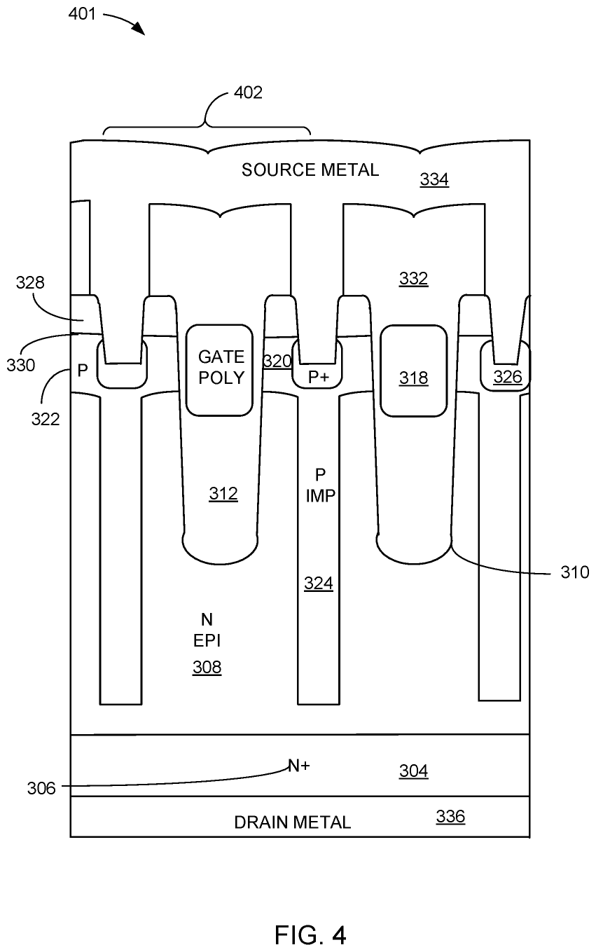

Referring now to FIG. 4 therein is shown an exemplary cross-section 401 of the integrated circuit system 100 along the section line 3-3 of FIG. 2 in an alternative embodiment of the present invention. In this example, the cross-section of the integrated circuit system 100 depicts two of a stripe gate cell 402 in the active region 104 of FIG. 1.

In this example, the stripe gate cell 402 can be formed similarly to split gate super junction cell 302. Continuing with this example, the stripe gate cell 402 can also be formed without the deposition of the stripe poly layer 314 of FIG. 3. By way of an example, the position of the stripe gate poly layer 318 is determined by the liner oxide layer 312 fills the space within the stripe gate trench 310. The liner oxide layer 312 is etched back to 0.6 μm below the silicon surface 330 before depositing the stripe gate poly layer 318 to fill the stripe gate trench 310.

It has been discovered that the stripe gate cell 402 can provide faster switching, higher break-down voltage (BV), and low conduction resistance (Rdson) based on the split gate super junction cell 302 construction and the presence of the conductive column 324. It is understood that the first polarity 306 is shown to be N-type doped silicon and the second polarity is shown to be P-type doped silicon, but the first polarity and the second polarity can be reversed. The stripe gate cell 402 can also provide improved linear mode of operation due to the conductive column 324 providing additional voltage blocking capability.

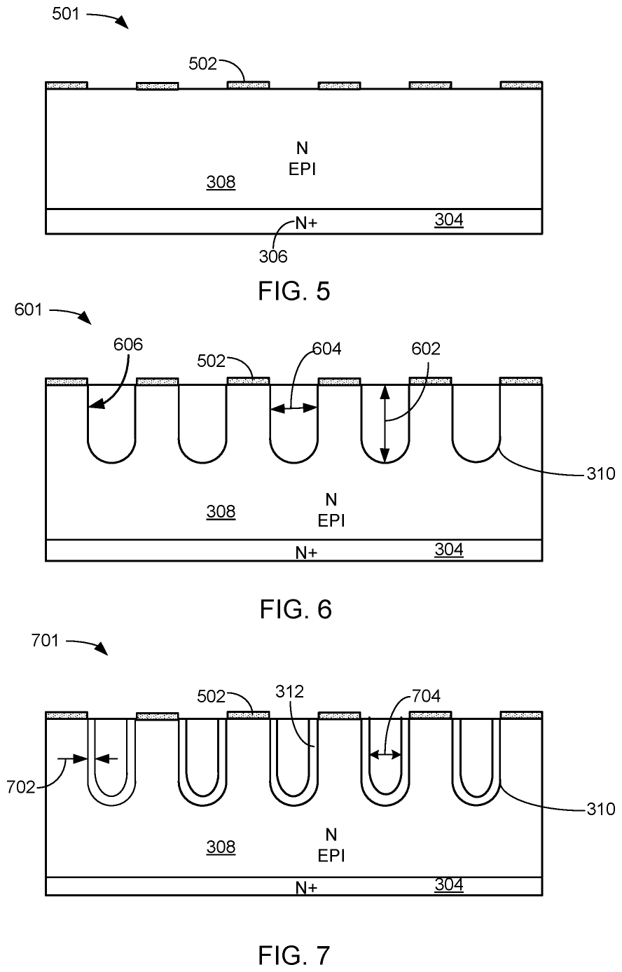

Referring now to FIG. 5, therein is shown an exemplary cross-section of a wafer portion 501 after a masking phase of processing. The exemplary cross-section of the wafer portion 501 depicts the heavily doped substrate 304, including the first polarity 306, can be covered by the epitaxial layer 308, also including the first polarity 306.

A masking layer 502 can be patterned on the surface of the epitaxial layer 308 opposite the heavily doped substrate 304. In this example, the masking layer 502 can be formed of a 3000 A deposition of oxide formed by CVD. The masking layer can define the area exposure of the epitaxial layer 308 that will be exposed for the next processing step.

Referring now to FIG. 6, therein is shown is an exemplary cross-section of a wafer portion 601 after a trenching phase of processing. In this example, the cross-section of the wafer portion 601 depicts the epitaxial layer 308 including an array of the stripe gate trench 310 formed therein.

As an example, the stripe gate trench 310 can be formed by a dry etch process giving tight control for the dimensions of the stripe gate trench 310. Also for example, the stripe gate trench 310 can include a depth 602 of substantially 1.0 μm and a width 604 of 0.45 μm+/−0.2 μm. The depth 602 and the width 604 allow the next phase of processing to be performed.

Referring now to FIG. 7, therein is shown an exemplary cross-section of a wafer portion 701 after an oxide deposition phase of processing. In this example, the cross-section of the wafer portion 701 depicts the liner oxide layer 312 grown on the interior portion of the stripe gate trench 310 to a thickness 702 of 0.1 μm.

As an example, the liner oxide layer 312 in the active area 104 and the isolation space are coated in the same manner Also, for example, the dimensions of the liner oxide layer 312 leave an opening 704 that is 0.10 μm to 0.50 μm within the stripe gate trench 310.

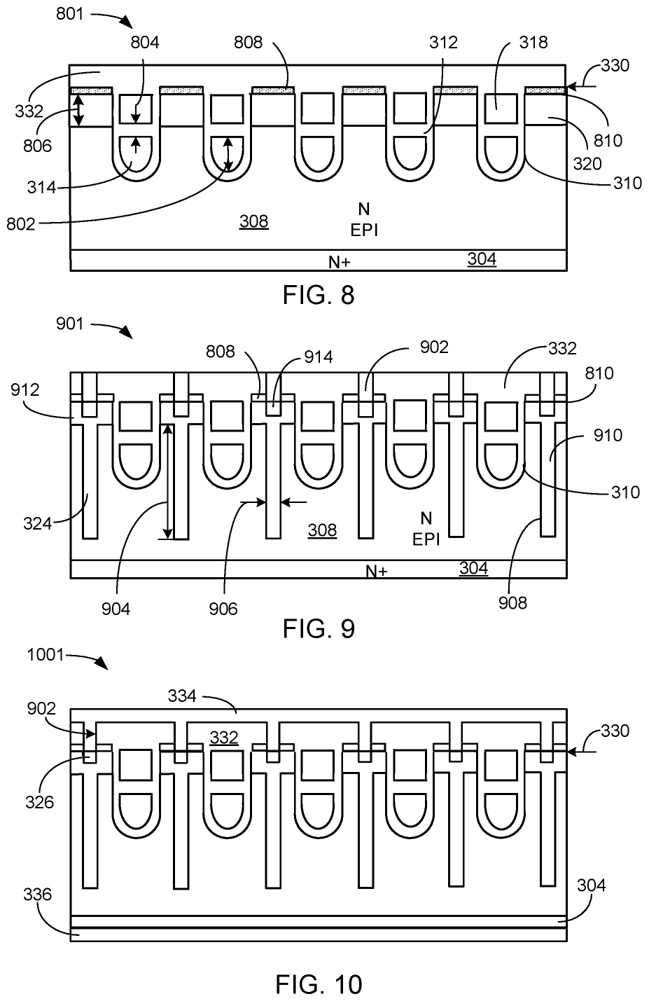

Referring now to FIG. 8, therein is shown an exemplary cross-section of a wafer portion 801 after a poly deposition and implant phase of processing. In this example, the cross-section of the wafer portion 801 depicts the stripe poly layer 314 including the liner oxide layer 312 that can be deposited and etched back 0.60 μm leaving a poly layer depth 802 of 0.15 μm. Also, for example, the liner oxide layer 312 can be deposited by CVD to fill the stripe gate trench 310 and then etched back 0.6 μm to provide a dielectric thickness 804 of 0.15 μm over the stripe poly layer 314.

As an example, the stripe gate poly layer 318 can be deposited to fill the stripe gate trench 310 and etched back to the silicon surface 330, leaving the second poly layer with a depth of 0.6 μm. Continuing the example, the body implant 320 can be implanted, in the silicon surface 330 between the instances of the stripe gate trench 310, including the second polarity 322 using Boron at a dose of 1e¹³/cm². After the body implant 320, a furnace process can be applied for driving the body implant 320 to a body drive-in depth 806 such as 0.50 um. a source layer 808 can be implanted over the body implant 320. The source layer 808 can of the first polarity at a dose of at a dose of 4e¹⁵/cm² to form the source layer 808. A body drive-in process can be performed in a 900° C. furnace process or a rapid thermal anneal (RTA), for forming a source and body contact 810 After the body drive-in process, the oxide cover 332 can be formed of LTO/BPSG oxide, which can be deposited on the silicon surface 330 with a thickness of 0.3 μm to 0.6 μm.

Referring to FIG. 9, therein is shown an exemplary cross-section of a wafer portion 901 after an ion implant phase of processing. The stripe source contact implant 326 can be accessed through an etched ditch 902, which can be formed by dry etching of the cover oxide 332 and the source layer 808.

In this example, the cross-section of the wafer portion 901 depicts the formation of the conductive column 324, which can be centered in the body implant 912 through the etched ditch 902. The conductive column 324 can be implanted including the second polarity 322. For example, the implant process can use Boron at a dose of 1e¹³/cm² at five steps of implant energy, such as such as 300 keV/600 keV/1 MeV/1.5 MeV/2.0 MeV. As a specific example, the purpose is to make a P-type column connection to the P-type body junction. Further for example, the resulting conductive column 324 extends below the body implant 320 and extends into the epitaxial layer 308 to form a column depth 904 of substantially 2.0 μm and has a column width 906 of substantially 0.5 μm.

After the formation of the etched ditch 902, a source implant process is performed with the first polarity 306 at a dose of 4e¹⁵/cm² to form the stripe source contact implant 326. Then, the etched ditch 902 can be formed by a dry etch process of the BPSG/LTO and Silicon to substantially a depth of 0.30 μm. The stripe source contact implant 326 can be implanted through the etched ditch 902. A stripe contact implant 914 is of the second polarity 322 with heavy dosing. Also, for example, the stripe contact implant 914 can be formed by implanting BF2 in a dose of 1e¹⁵/cm² and activated by a furnace process or rapid thermal anneal (RTA) process.

In an alternative embodiment and example, the conductive column 324 can be formed by implementing a dry etch trench 908 in the epitaxial layer 308 and filling the trench with a column epitaxial layer 910 of the second polarity 322. By way of a specific example, the dry etched trench 908 can be filled with a P-type epitaxial layer to form the P-type of the column epitaxial layer 910. As an example, the embodiment can be utilized for medium voltage (60 V to 250 V) and high voltage devices operating over 250 Volts.

It has been discovered that the conductive column 324 or the column epitaxial layer 910 can reduce the Drain/Source conduction resistance (Rdson) to allow high voltage blocking capability and improve linear mode operation. The column depth 904 can increase for higher voltage devices. By way of an example, the integrated circuit die 102 of FIG. 1 that operates below 40 V can utilize the column width 906 of substantially 0.5 μm and the column depth 904 of substantially 2.0 μm. The integrated circuit die 102 can operate in medium voltage range (60V to 250V) to high voltage range (such as 600V above). For medium voltage (60V to 250V), the column width 906 is in a range of 0.5 μm to 2 μm, and the column depth 904 in a range of 2.0 μm to 15 μm. For high voltage (600V to 650V and above), the column width is in a range of 2.0 μm to 6.0 μm, and the column depth is in a range of 40 μm to 60 μm.

Referring now to FIG. 10, therein is shown an exemplary cross-section of a wafer portion 1001 in a metal deposition phase of processing. In this example, the cross-section of the wafer portion 1001 depicts the oxide cover 332, which can be formed of LTO/BPSG oxide, deposited on silicon surface 330.

The source metal 334 can be deposited into the etched ditch 902 to couple the source metal 334 to the stripe contact implant 326. The source metal 334, such as Aluminum (Al), Copper (Cu), or an alloy thereof, can be deposited on the oxide cover 332, the etched ditch 902 and on the stripe contact implant 326. The heavily doped substrate 304 can be exposed for deposition of the drain metal 336, such as Nickel (Ni), Silver (Ag), Copper (Cu), or an alloy thereof.

The column with the second polarity also can be stripe shaped. The gate trench also can be closed cell type in this invention.

The source metal 334, such as Aluminum (Al), Copper (Cu), or an alloy thereof, can be deposited on the oxide cover 332, the etched ditch 902 and on the stripe contact implant 326. The heavily doped substrate 304 can be exposed for deposition of the drain metal 336, such as Nickel (Ni), Silver (Ag), Copper (Cu), or an alloy thereof.

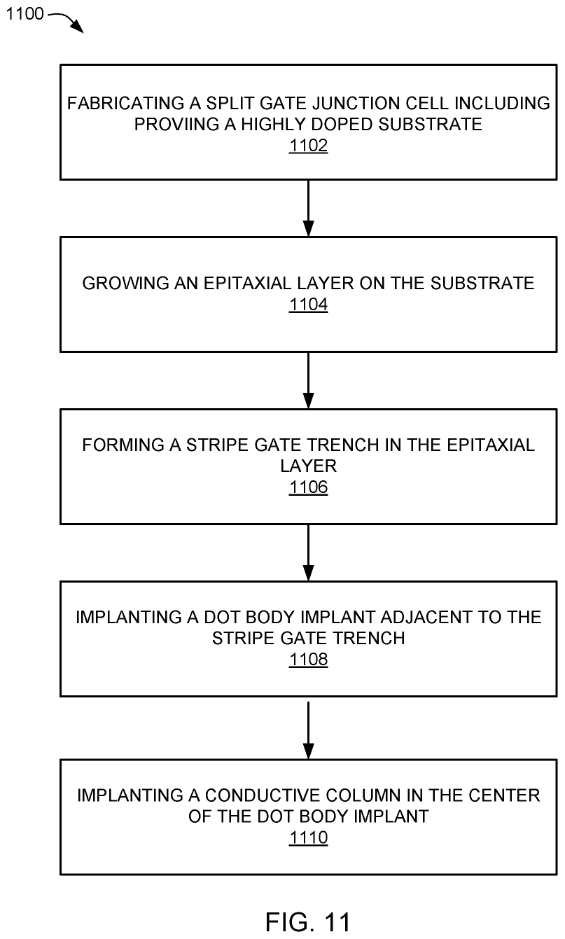

Referring now to FIG. 11, therein is shown a flow chart of a method 1100 of manufacture of the integrated circuit system 100 in an embodiment of the present invention. The Method 1100 includes: fabricating a split gate super junction cell providing a highly doped substrate including a first polarity in a block 1102; growing an epitaxial layer including the first polarity on the highly doped substrate in a block 1104; forming a stripe gate trench in the epitaxial layer in a block 1106; implanting a body implant, including a second polarity, adjacent to the stripe gate trench opposite the stripe gate poly layer in a block 1108; and implanting a conductive column, including the second polarity, in the center of the body implant and extending into the epitaxial layer in a block 1110.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. An integrated circuit system comprising:
a split gate super junction cell including:
a highly doped substrate including a first polarity;
an epitaxial layer including the first polarity grown on the highly doped substrate;
a stripe gate trench in the epitaxial layer;
a stripe gate poly layer in the stripe gate trench;
a body implant, including a second polarity, adjacent to the stripe gate trench opposite the stripe gate poly layer; and
a conductive column, including the second polarity, in the center of the body implant and extending into the epitaxial layer.

2. The system as claimed in claim 1 wherein the stripe gate trench, in the epitaxial layer, includes a liner oxide layer on an interior of the stripe gate trench.

3. The system as claimed in claim 1 further comprising a stripe split gate structure by a split poly layer in the stripe gate trench with the stripe gate poly layer above the split poly layer.

4. The system as claimed in claim 1 further comprising a stripe source contact implant on the dot body implant and centered over the conductive column in an active region.

5. The system as claimed in claim 1 further comprising an oxide cover on the stripe gate poly layer and above the body implant.

6. The system as claimed in claim 1 wherein the stripe gate trench includes a depth of 1.0 μm and a width of 0.45 μm+/−0.2 μm.

7. The system as claimed in claim 1 wherein the conductive column includes a column depth of 2.0 μm and a column width of 0.5 μm based on a 30V breakdown voltage.

8. The system as claimed in claim 1 wherein the conductive column is in a column trench and filled by a column epitaxial layer including the second polarity.

9. A system as claimed in claim 1 further comprising a source metal on an oxide cover and through an etched ditch in the oxide cover, wherein the etched ditch, with implanted BF₂, at a concentration of 1 e¹⁵/cm³ and a 900° C. furnace process or a rapid thermal anneal (RTA), for forming a source and body contact.

10. A system as claimed in claim 1 further comprising an active region and a termination region, wherein the termination region includes an isolation space with a floating trench surrounding the active region.

11. A method of manufacture of the integrated circuit system comprising:
fabricating a split gate super junction cell including:
providing a highly doped substrate including a first polarity;
growing an epitaxial layer including the first polarity on the highly doped substrate;
forming a stripe gate trench in the epitaxial layer;
implanting a body implant, including a second polarity, adjacent to the stripe gate trench opposite the stripe gate poly layer; and
implanting a conductive column, including the second polarity, in the center of the body implant and extending into the epitaxial layer.

12. The method as claimed in claim 11 further comprising forming a liner oxide layer on the interior of the stripe gate trench.

13. The method as claimed in claim 11 further comprising forming a stripe split gate structure including depositing a split poly layer in the stripe gate trench and depositing the stripe gate poly layer above the split poly layer.

14. The method as claimed in claim 11 further comprising forming a stripe source contact on the body implant and centered over the conductive column.

15. The method as claimed in claim 11 further comprising forming a cover oxide on the stripe gate poly layer and above the body implant.

16. The method as claimed in claim 11 wherein forming a stripe gate trench, in the epitaxial layer, includes the stripe gate trench including a depth of 1.0 μm and a width of 0.45 μm+/−0.2 μm.

17. The method as claimed in claim 11 wherein implanting the conductive column includes implanting the conductive column to a column depth of 2.0 μm and a column width of 0.5 um based on a 30V breakdown voltage.

18. The method as claimed in claim 11 wherein implanting the conductive column includes forming a column trench and filling with a column epitaxial layer including the second polarity.

19. The method as claimed in claim 11 further comprising:
etching an etched ditch through a cover oxide and a masking layer;
implanting the etched ditch, with BF₂ at a concentration of 1 e¹⁵/cm³ and a 900° C. furnace process or a rapid thermal anneal (RTA), for forming a source and body contact; and
depositing the source metal on the oxide cover and through the etched ditch.

20. The method as claimed in claim 11 further comprising providing an active region and a termination region, wherein the termination region includes an isolation space including a floating trench surrounding the active region.
